(19) United States
(12) Patent Application Publication
(10) Pub. No.: US 2026/0328492 A1
(43) Pub. Date: Oct. 22, 2026

(54) SYSTEM AND METHOD OF THERMAL MANAGEMENT

(71) Applicant: Lockheed Martin Corporation, Bethesda, MD (US)

(72) Inventors: Aleksandra Shepsis, Mill Creek, WA (US); Thomas Robert Derco, Warrenton, VA (US); Joseph Thomas South, Bel Air, MD (US); Carlos Mendez, Seattle, WA (US); James Douglass Weigner, Clay, NY (US)

(21) Appl. No.: 19/186,561

(22) Filed: Apr. 22, 2025

(51) Int. Cl. F28D 21/00; F28D 11/06; H02K 44/08; H02K 44/12; H02K 44/26; H05K 7/20

(52) U.S. Cl. CPC F28D 21/0001; F28D 11/06; H02K 44/085; H02K 44/12; H02K 44/26; H05K 7/20327; H05K 7/20336

(57) ABSTRACT

A thermal management system, the system including a thermal structure forming a plurality of channels, the thermal structure being a thermally conductive material, a cooling fluid configured to flow through the channels of the thermal structure, the cooling fluid being an electrically conducting fluid, and a drive system configured to pump the cooling fluid through the channels of the thermal structure, wherein the drive system controls one or more electromagnetic field to induce magnetohydrodynamic pumping of the cooling fluid.

### TECHNICAL FIELD

The present disclosure relates to thermal management, and more particularly to thermal management systems for use in various applications ranging from high power electronics to extreme thermal conditions.

### BACKGROUND

Thermal management for high power electronics is increasingly challenging as system power is increased in smaller electronic packaged systems. Currently, high power computing is cooled in many different ways, each with its limitations, complexities, or undesirable SWaP (Size, Weight, and Power) impacts.

Forced air convection reaches its limits in heat transfer efficiency due to the constraints of fan flow curves. High flowing fans can mitigate some of these issues, but they introduce significant noise, which is undesirable in commercial applications. This method also struggles with localized heating problems, where certain areas of the system may overheat despite overall adequate cooling.

Integrated heat pipes offer a passive cooling solution by conducting heat away from hot spots. However, they are limited in their cooling capacity and can be quite expensive to implement. Heat pipes primarily function by moving heat from one location to another, rather than dissipating it, which can lead to inefficiencies in thermal management.

Integrated liquid and two-phase cooling loops present another option for managing high power electronics. These systems can handle higher heat loads but come with their own set of challenges. They tend to be larger and heavier, with more components that add to the system's complexity. The need for motor-driven components to induce flow further complicates the design, impacting system reliability, SWaP, and overall cost.

Existing thermal management approaches for Hypersonic Glide Vehicles present significant challenges due to the exposure to extreme conditions. The nose area is subjected to high ablation must be constructed to withstand the intense thermal and mechanical stresses encountered during hypersonic flight. Constructing these structures to endure the extreme hypersonic temperatures exceeding 1000 K poses formidable bonding and material forming technical challenges. It requires precise alignment and bonding techniques to ensure structural cohesion and thermal efficiency. These challenges hinder the effectiveness and reliability of current thermal management solutions, as any imperfections in the bonding or material forming processes can lead to structural failures or reduced thermal performance.

Accordingly, there is a need for high performing thermal management systems which seek to improve reliability, have a favorable SWaP, minimize complexity, and reduce overall cost.

### SUMMARY

In one aspect, the present disclosure provides thermal management system, the system including a thermal structure forming a plurality of channels, the thermal structure being a thermally conductive material, a cooling fluid configured to flow through the channels of the thermal structure, the cooling fluid being an electrically conducting fluid, and a drive system configured to pump the cooling fluid through the channels of the thermal structure, wherein the drive system controls one or more electromagnetic field to induce magnetohydrodynamic pumping of the cooling fluid.

In another aspect, the present disclosure provides a thermal management system including a thermal structure forming a plurality of channels, the thermal structure is an additively manufactured ceramic structure and/or any electrically non-conductive structure, a cooling fluid configured to flow through the channels of the thermal structure, the cooling fluid being an electrically conducting metal, one or more sets of electrodes configured to apply a current to the system, and a drive system configured to pump the cooling fluid through the channels of the thermal structure, the drive system operatively coupled to the one or more sets of electrodes to control the current applied to the system and induce magnetohydrodynamic pumping of the cooling fluid.

In yet another aspect, the present disclosure provides a thermal management system including a thermal structure forming a plurality of channels, the thermal structure being a thermally conductive material, the thermal structured having a first end, a second end, a first side extending between the first end and second end, a second side opposite the first side and extending between the first end and the second end, a bottom extending between the first end and the second end, and a top opposite the bottom and extending between the first end and the second end. A pair of electrodes is positioned along the first side and the second side of the thermal structure, the pair of electrodes configured to induce a current between first side and the second side of the thermal structure. One or more magnets is positioned along the bottom of the thermal structure, the one or more magnets is configured to induce a magnetic field perpendicular to the current. A cooling fluid configured to flow through the channels of the thermal structure, the cooling fluid being an electrically conducting fluid. A control system is configured to control magnetohydrodynamic pumping of the cooling fluid by controlling the current flowing between the pair of electrodes.

Other features and aspects of the disclosure will become apparent by consideration of the following detailed description and accompanying drawings.

### BRIEF DESCRIPTION OF THE DRAWINGS

FIG. 1 is an example of a thermal management system according to one embodiment.

FIG. 2 is another example of a thermal management system according to another embodiment.

FIG. 3A is an example of a portion of a thermal structure with a Triply Periodic Minimal Surface.

FIG. 3B is another example of a portion of a thermal structure with a Triply Periodic Minimal Surface.

FIG. 4 is a cross-sectional view of a thermal management system in a steady state with a representation of a thermal analysis without the cooling fluid.

FIG. 5 is a cross-sectional view of the thermal management system of FIG. 4 in a steady state with a representation of a thermal analysis with the cooling fluid.

FIG. 6 illustrates an exemplary embodiment of a moving platform to create a dynamic magnetic field.

### DETAILED DESCRIPTION

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways. Also, it is to be understood that the phraseology and terminology used herein is for the purpose of description and should not be regarded as limiting.

### Thermal Management System

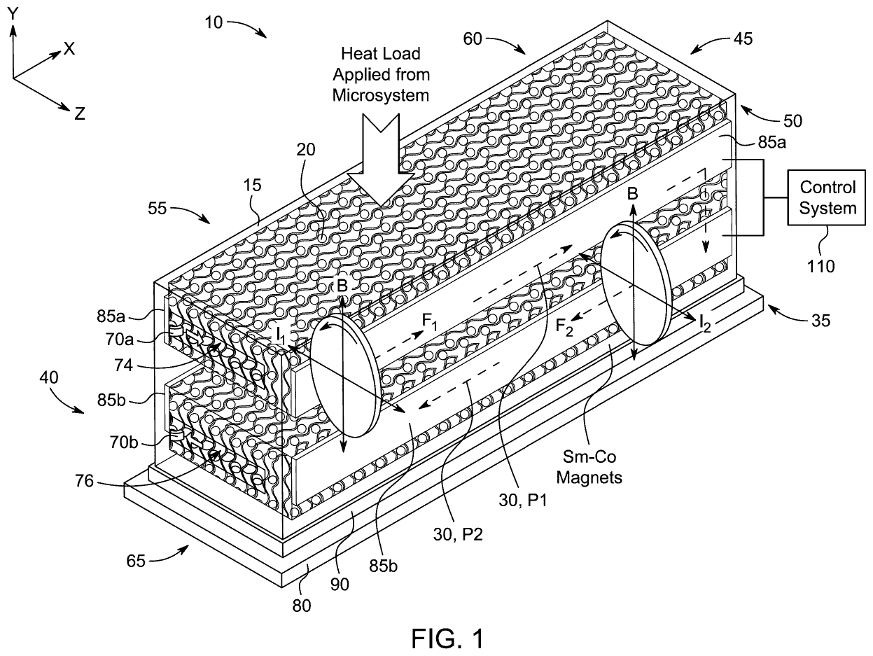

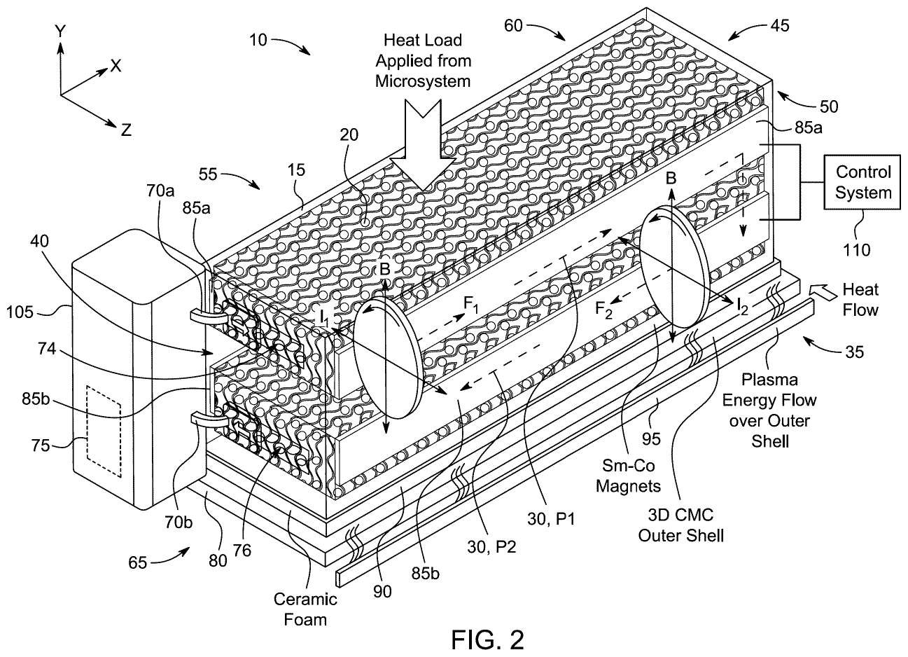

FIGS. 1-2 illustrate embodiments of a thermal management system 10 according to the present disclosure. It should be understood that these are only exemplary embodiments and that different arrangements or variations of features may be present in alternative embodiments. The thermal management system 10 (or heat exchanger) includes a housing 15 having a thermal structure 20 forming a plurality of channels 25 (i.e., a manifold). As used herein, the term thermal structure is intended to include various structures akin to a lattice structure, a Triply Periodic Minimal Surface (TPMS), an iso-grid, or a plurality of fins, or a combination thereof. In some embodiments, the thermal structure 20 may be a porous structure. A cooling fluid 30 is configured to flow through the channels 25 of the thermal structure 20. The cooling fluid 30 is an electrically conducting fluid, which may be pumped through the channels 25 of the thermal structure 20 using magnetohydrodynamic pumping. In some embodiments, the cooling fluid 30 is an electrically conducting metal, however, other electrical conducting materials may be used depending on the implementation. A drive system 35 is configured to pump the cooling fluid 30 through the channels 25 of the thermal structure 20 by controlling the amount of the current applied to the electrodes 85 on the thermal management system 10 or changing the electromagnetic field surrounding the thermal management system 10 to induce the desired magnetohydrodynamic pumping of the cooling fluid 30. The thermal management system 10 leverages magnetohydrodynamic pumping to circulate cooling fluid 30 internally within the thermal structure 20 from the hot zone to the cold zone. The cooling fluid 30 circulation via magnetohydrodynamic pumping of the cooling fluid 30 through the thermal structure 20 generates an efficient forced coolant convection that allows efficient heat transfer from the hot zone to the cold zone in an integrated thermal management system 10.

As will be described in further detail below, the thermal management system 10 may be utilized in a wide variety of implementations ranging from high powered electronics to hypersonic vehicles. As used herein, the term “item to be cooled” will generally refer to the various implementations of the thermal management system 10.

### Thermal Management System

The thermal management system 10 includes a housing 15 with a thermal structure 20 designed to enhance thermal management and structural integrity. In some embodiments, the thermal structure 20 is free standing without a defined housing 15. For example, if the thermal structure 20 is built directly within the item to be cooled, the thermal management system 10 may not include a separate defined housing beyond the walls of the item to be cooled. In other embodiments, the thermal management system 10 may have its own separate housing 15. As used herein, the term “housing 15” may be used to refer to either one of these situations. The housing 15 may have many different shapes and sizes depending on the specific implementation. In the illustrated embodiment the housing 15 is generally shaped as a rectangle with a first end 40, a second end 45 opposite the first end 40, a first side 50, a second side 55 opposite the first side 50, a top 60, and a bottom 65 opposite the top 60. The first side 50, second side 55, top 60, and bottom 65 all extend between the first end 40 and the second end 45. The housing 15 includes an inlet 74 through which cooling fluid 30 may enter and an outlet 76 through which cooling fluid 30 may exit. In the illustrated embodiment, the cooling fluid 30 flows through a closed loop, and as such, the inlet 74 and the outlet 76 are both positioned on the first end 40.

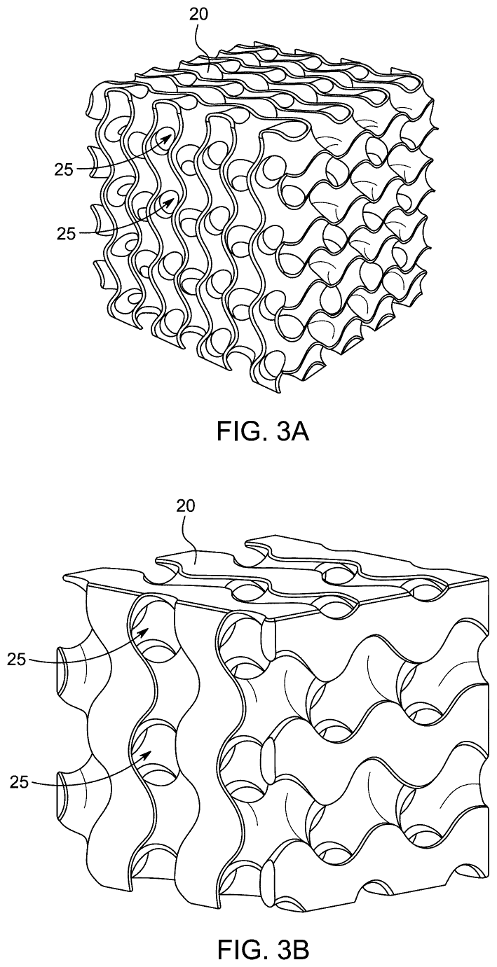

The thermal structure 20 is shaped to form a series of channels 25 through which fluid may flow. In some embodiments, the thermal structure 20 may be shaped as a Triply Periodic Minimal Surface (TPMS), which is advantageous for increased heat transfer while maintaining sufficient strength. The Triply Periodic Minimal Surface geometry provides a large surface area to transfer heat. FIGS. 3A and 3B are exemplary embodiments of a portion of lattice structure 20 having a Triply Periodic Minimal Surface. The thermal structure 20 may be additively manufactured in order to create the Triply Periodic Minimal Surface shape, which is otherwise difficult to manufacture using traditional manufacturing techniques. In some embodiments, the thermal structure 20 may be additively manufactured directly onto the surface of the item being cooled, ensuring seamless integration and optimal performance. Additively manufacturing the thermal structure 20 directly onto the surface of the item being cooled improves structural integrity and connectivity of the thermal structure 20 to the item being cooled. In other embodiments, the thermal structure 20 may be bonded to the item being cooled after being additively manufactured separately.

A thermally conductive material is used to form the thermal structure 20. For example, a porous high temperature material, such as a porous ceramic, a ceramic matrix composite (CMC), or continuous carbon fiber ceramic matrix composite components may be used to form the thermal structure 20. In some embodiments, a material such as silicon carbide (SiC) or other thermal conductive ceramic materials may be used to form the thermal structure 20. The thermal structure 20 may be additively manufactured with a ceramic material, such as a silicon carbide material. The additive manufacturing of such ceramic material (i.e. SiC) may be achieved through a variety of additive manufacturing processes and/or any material that is electrically non-conductive. In some embodiments, the thermal structure 20 may be composed of blended ceramics and/or blended ceramics to metal components.

Furthermore, by additively manufacturing a thermal structure 20 using multiple materials allows for the integration of current conductors into the thermal structure 20. For example, copper (Cu) or Titanium may be directly fused to the ceramic via Laser Powder Bed Fusion (LPBF). This allows for precise and efficient deposition of copper, enhancing and controlling the thermal conductivity of the housing 15 structure. As will be explained in further detail below, this technique may be implemented to develop a magnetic field used to drive the magnetohydrodynamic pumping of the cooling fluid 30. Additionally, the blended material capability enables the thermal structure 20 to be connected and/or mounted to the desired component of the item to be cooled. Alternatively, the thermal structure 20 may be additively manufactured by 3D printing continuous carbon fiber ceramic matrix composite components. In other embodiments, different types of additive manufactured composite structures and materials may be used. The materials used in the additive manufacturing process are carefully selected to maximize thermal conductivity, structural integrity, and connectivity capabilities.

Referring to FIGS. 1 and 2, the thermal structure 20 may include one or more section 70 layer(s). The sections 70 may be partially or fully separated from one another, for example, by a dividing structure, but may be positioned adjacent to one another for flow there between. For example, in the illustrated embodiment, the thermal structure 20 includes a first section 70a (i.e., a first level) and a second section 70b (i.e., a second level) positioned adjacent the first section 70a. The cooling fluid 30 may flow in different directions within each of the sections 70. The ability to pump the fluid in different directions within each section 70 allows for the cooling fluid 30 to flow through a closed loop. In the illustrated embodiment, the cooling fluid 30 flows in a first direction (i.e., from left to right as shown in the figures) in the first section 70, and flows in a second direction (i.e., from right to left as shown in the figures) in the second section 70. In another exemplary embodiment, the thermal structure 20 may include four sections 70 forming a square. In such an example, the cooling fluid 30 may flow in four different directions (i.e., a different direction in each section 70) around the square thermal structure 20 in order to complete a closed loop. The thermal structure 20 may have any number of different sections 70 arranged in a variety of different configurations that form a closed loop. As will be understood, the shape of the thermal structure 20 and the number of sections 70 will be determined based upon the size and shape of the item to the cooled, as well as the amount of heat necessary to remove.

Referring to FIGS. 1 and 2, the thermal management system 10 may include a reservoir 75 to house the cooling fluid 30. The cooling fluid 30 may be stored within the reservoir 75 when the thermal management system 10 is not in operation. In some embodiments, the reservoir 75 may be integrated into the flow path of the cooling fluid 30 as a part of the closed loop. In other embodiments, the reservoir 75 may be offset from the flow path of the closed loop. For example, in some embodiments, the reservoir 75 may be connected or aligned with the inlet 74 and the outlet 76 of the housing 15. The reservoir 75 can be used to maintain the temperature of the cooling fluid 30 until flow thru the thermal management system 10 is required.

The thermal management system 10 may include an insulating layer 80 for protecting internal components from external ambient temperatures and/or reduce thermal losses from the outside environment. The insulating layer 80 may be composed of Silicon Carbide (SiC) foam or other materials having thermal insulation properties. This layer ensures that the internal components remain unaffected by temperature fluctuations, thereby enhancing the overall reliability and longevity of the system.

The additively manufactured geometry that integrates the thermal structure, mechanical structure, flow distribution features, electrode features, magnetic feature, cooling interfaces, and heat extracting interfaces all integrated and additively manufactured into a simple, reliable, and low-cost assembly part.

### Cooling Fluid

The thermal management system 10 includes a cooling fluid 30 (represented by flow arrows) configured to flow through the channels 25 of the thermal structure 20. The cooling fluid 30 is thermally conductive, and thereby capable of absorbing and removing heat from the item to be cooled. The cooling fluid 30 is also an electrically conducting material capable of being manipulated by magnetohydrodynamic pumping and/or thermo-hydrodynamic pumping. For example, in some embodiments the cooling fluid 30 is an electrically conducting metal. The cooling fluid 30 may be stored in the reservoir 75 when the thermal management system 10 is not operating. As the cooling fluid 30 is utilized it flows through the thermal structure 20 in a closed loop and can eventually return back to the reservoir 75.

In some embodiments, the cooling fluid 30 may be stored in a solid phase and melted to a fluid phase during operation of the thermal management system 10. This increases the thermal capacity of the system by maximizing the thermal capacity from solid to liquid phase as the heat is absorbed by the cooling fluid 30. In such an embodiment, the cooling fluid 30 may have a low melting point in order to ease the transition from a solid phase to a liquid phase. If the cooling fluid 30 is maintained in a solid state for too long, it may allow certain areas of the system to overheat before the cooling fluid 30 is able to flow through the system and remove heat. Therefore, while the transition from solid to liquid phase helps maximize thermal capacity by absorbing an initial amount of heat, it is also important to leverage a low melting point to allow the cooling fluid 30 to begin flowing through the thermal structure 20. In some embodiments, the cooling fluid 30 may be Galinstan or other Gallium (Ga) based alloys. However, other types of materials may be used as cooling fluids 30 depending on the implementation. In other embodiments, the cooling fluid 30 could also be stored in liquid phase and transition to vapor phase as it absorbs heat from the hot zone. Latent heat transfer of the cooling fluid 30 maximizes the thermal capacity of the system and allows for movement of the coolant via passive convection. This embodiment allows for integration of heat pipe technology with the proposed integrated magnetohydrodynamic pumping of the fluid prior to phase transition.

Although movement of the cooling fluid 30 through the thermal structure 20 is primarily described as being the result of magnetohydrodynamic pumping, the cooling fluid 30 may also be moved through the thermal structure 20 by way of passive fluid convection as the cooling fluid 30 circulates internally within the thermal management system 10 from the hot zone to the cold zone, similar to an oscillating or pulsating heat pipe configuration. Accordingly, the thermal management system 10 leverages passive fluid convection as a vaporized liquid circulates internally within the structure from the hot zone to the cold zone and/or magnetohydrodynamic pumping of the liquid internally within the structure from the hot zone to the cold zone.

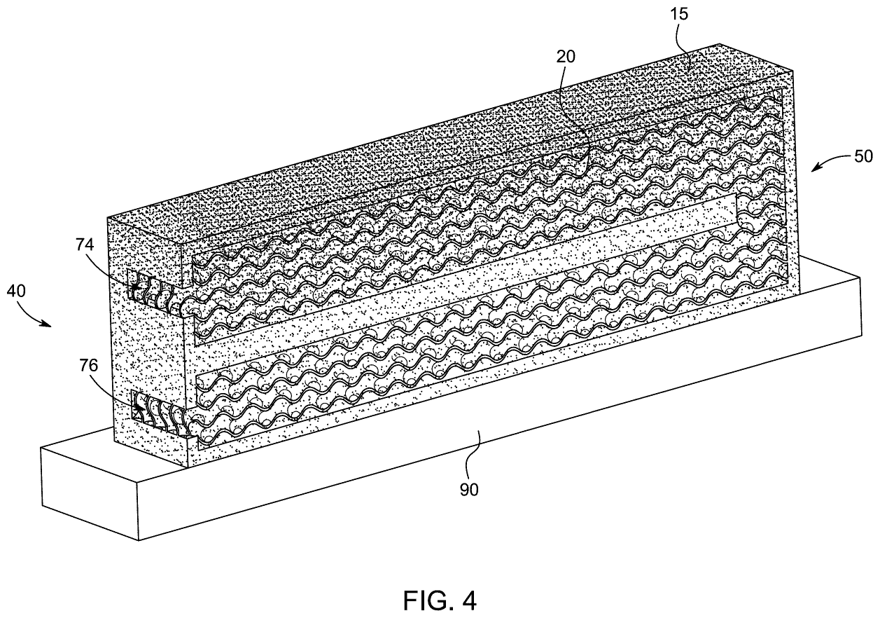

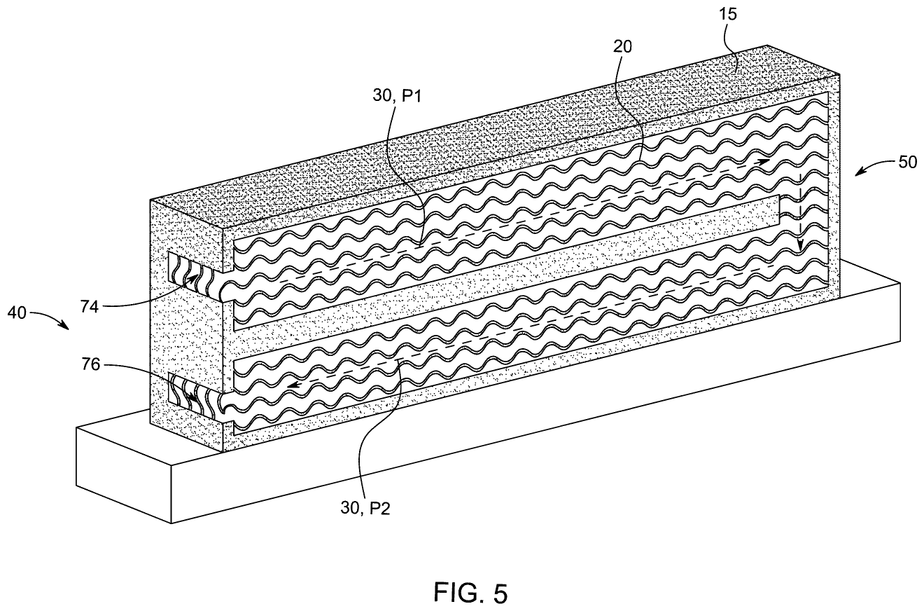

FIGS. 4-5 illustrate the effects of the cooling fluid 30 as it flows through the thermal structure 20. Specifically, FIG. 4 shows the thermal structure 20 under a steady state thermal analysis without the cooling fluid 30. FIG. 5 shows the thermal structure 20 in a steady state thermal analysis with the cooling fluid 30 present. As can be seen from these figures, the cooling fluid 30 reduces the thermal footprint and creates a more even distribution of heat.

### Drive System

The drive system 35 is configured to pump the cooling fluid 30 through the channels 25 of the thermal structure 20 via magnetohydrodynamic pumping. The drive system 35 provides for a simplistic system with few components, a low size, low weight and power (SWaP), and less expensive components (in some implementations) while still maintaining its reliability. For example, the drive system 35 is capable of pumping cooling fluid 30 through the thermal structure 20 without additional mechanical pumps, coolant valves, hydraulic controls, motors, etc. This reduces the cost, complexity, and SWaP of the thermal management system 10 and the item to be cooled (i.e., the main product that houses the thermal management system 10).

The drive system 35 pumps the cooling fluid 30 through the thermal structure 20 by Lorentz force, which is generated by the combination of an orthogonal magnetic field and perpendicular current imposed to the cooling fluid 30. The drive system 35 creates, harnesses, and/or controls the magnetic field and the current imposed to the cooling fluid 30 in order to control the magnetohydrodynamic pumping of the cooling fluid 30. This makes it possible to “pump” the cooling fluid 30 without any external rotating machinery or an actual pump.

The drive system 35 may include a control system 110 that enables control of the electromagnetic fields, current, and/or energy to thereby control the magnetohydrodynamic movement of the cooling fluid 30 through the thermal structure 20. In one embodiment, the control system 110 may include one or more processor(s), one or more sensor(s), and a power supply. In another embodiment, the thermal management system 10 can be simplified without needing a control system of its own by leveraging the existing controller on the assembly it thermally manages. In this embodiment, the thermal management system 10 will have an electrical interface that would require current supply, depending on the desired system temperature regulation.

FIGS. 1 and 2 provide two examples of a thermal management system 10 in which the drive system 35 utilizes a magnetic field and current to control the cooling fluid 30. The magnetic field (B) is directed upward along the y-direction. In the first section 70 of the thermal structure 20, the current (I₁) is flowing in a first direction into the page along the z-direction, which creates a force (F₁) causing the cooling fluid 30 to flow from left to right along the x-direction. This is the first flow path (P₁) of the closed loop, which can also be seen in FIG. 5. In the second section 70 of the thermal structure 20, the current (I₂) is flowing in a second direction out of the page along the z-direction, creating a force (F₂) in the orthogonal direction causing the cooling fluid 30 to flow from right to left along the x-direction. This is the second flow path (P₂) of the closed loop, which can also be seen in FIG. 5. As previously discussed, the thermal structure 20 may have many different sections 70 and arrangements depending on the item to be cooled. The cooling fluid 30 may be controlled to flow through various paths by changing the direction of the current and/or magnetic field.

The drive system 35 may control the flow rate of the cooling fluid 30 by adjusting the volumetric flow of the fluid generated by the electromagnetic force. This may be done by adjusting the current input into the thermal management system 10, and/or the magnetic field. Given the high thermal conductivity of liquid metal material, a volumetric flow rate of less than 0.1 GPM (0.38 L/min) can thermally manage components and heat loses absorbed from the hot exterior environments, ambient environments, or interior microsystems. As previously mentioned, the thermal capacity of the system may be increased by storing the cooling fluid 30 in a solid phase. Depending on the type of cooling fluid 30 that is utilized, additional capacity can be achieved by taking advantage of latent heat transfer with transitioning the cooling fluid 30 from liquid phase to gas phase.

Electric power and a magnetic field are required to create the Lorentz force necessary to drive the magnetohydrodynamic pumping of the cooling fluid 30. Depending on the implementation of the thermal management system 10, the power and magnetic field may be generated and/or controlled in different manners. Additionally, depending on the implementation, the drive system 35 may vary in both its operation and components. General concepts of how the drive system 35 operates will be described herein along with some exemplary embodiments. However, it should be understood that variations may occur depending on the particular implementation.

The drive system 35 may include electrodes 85 for providing current necessary for magnetohydrodynamic pumping. There may be electrodes 85 extending along the first side 50 and second side 55 of the thermal structure 20 (or portions of the thermal structure 20) to help induce the current. In the embodiments illustrated in FIGS. 1-2, a first set of electrodes 85a is positioned on opposite sides (i.e., first side 50 and second side 55) of the first section 70 of the thermal structure 20. The first set of electrodes 85a creates a current in the first section 70 of the thermal structure 20 into the page along the z-direction. When paired with a magnetic field in the upward direction along the y-direction, an electromagnetic force (Lorentz Force) is created in the x-direction to pump the cooling fluid 30 from left to right. A second set of electrodes 85b is positioned on opposite sides (i.e., first side 50 and second side 55) of the second section 70 of the thermal structure 20. The second set of electrodes 85b creates a current in the second section 70 of the thermal structure 20 coming out of the page along the z-direction. When paired with a magnetic field in the upward direction along the y-direction, an electromagnetic force (Lorentz Force) is created in the x-direction (opposite the force created in the first section 70) to pump the cooling fluid 30 from right to left. In some embodiments, the first set of electrodes 85a is mounted to the housing 15 adjacent the first section 70 of the thermal structure 20 and the second set of electrodes 85b is mounted to the housing 15 adjacent the second section 70 of the thermal structure 20.

The drive system 35 may include one or more magnet(s) 90 to create the magnetohydrodynamic flow of cooling fluid 30. In some embodiment, the magnetic field may be generated by a solid magnet 90 mounted near the thermal structure 20. For example, in the embodiments illustrated in FIGS. 1-2, the magnets 90 are positioned along the bottom 65 of the housing 15 structure just below the thermal structure 20. The magnets 90 extend along the x-axis of the thermal structure 20 between the first end 40 to the second end 45. The magnets 90 may be the primary source of the magnetic field or may be used to supplement other means of creating or harvesting a magnetic field. In some embodiments, the magnets 90 may be high temperature Sm—Co magnets 90 that have a Curie temperature of 500 degrees Celsius. However, it should be understood that different types of magnets 90 and different arrangements of magnets 90 may be used.

In another embodiment, the drive system 35 may utilize or harvest the magnetic field (or electric field) from a plasma 95 source. The drive system 35 may capture electrons generated by the plasma 95 field. The electric and/or magnetic fields created by the electron motion from the plasma 95 may be utilized and/or harvested for the magnetohydrodynamic pumping of the cooling fluid 30. An example of such an implementation is described in further detail below.

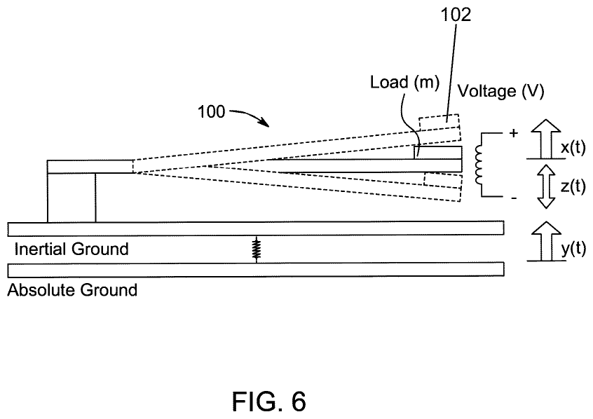

Furthermore, energy maybe harvested by the thermal management system 10 by providing an external source of flow. This can be accomplished by a variety of techniques such as kinetic energy applied to the thermal management system 10 or the product as a whole. Also current can be harvested via thermal electrical methods by utilizing Peltier effects. Energy may be harvested from the magnetic field using thermoelectric generation. In some embodiments, this method may involve using a moving platform 100 supporting a magnet 102 to create a dynamic magnetic field. FIG. 6 illustrates an exemplary embodiment of a moving platform 100 to create a dynamic magnetic field.

In some embodiments, electrical current may be generated with kinetic energy applied to the thermal management system 10, inducing the flow of the cooling fluid 30, and thus making the thermal management system 10 power neutral or power generating for other surrounding electrical components.

As shown in the embodiment of FIG. 2, energy can also be harvested with a pressurized integrated accumulator 105. The accumulator 105 can be used to generate external flow thru the thermal management system, allowing current to be harvested. The drive system 35 may include an integrated accumulator 105 to store energy that will ultimately be used to create power used to drive magnetohydrodynamic flow of the cooling fluid 30. The energy may be derived from a variety of different sources depending on the implementation of the thermal management system 10 that is being used.

### Example Implementations

### Example 1—Extreme Heat Conditions

The present disclosure may be used to address thermal management problems for harsh environments, such as extreme temperatures and speeds. Thermal protection and management of Hypersonic Glide Vehicles (HGV) is a challenging system problem, as temperatures can reach above 1000 degrees Celsius. Electronic Microsystems deployed within Hypersonic Glide Vehicles and space craft are exposed to surrounding temperature extremes during their flight. The present disclosure provides a promising, simple, low SWaP, and reliable thermal management technology, for high performance microsystems deployed within high-speed air or space vehicles, exposed to high temperature and/or high heat flux environments.

In one implementation, the temperature management system may be used to cool high heat flux components in objects moving at hypersonic speeds, such as Hypersonic Glide Vehicles. A body traveling at high speeds through the atmosphere can generate plasma 95 energy flow over the outer shell for energy harvesting.

As previously mentioned, the drive system 35 uses electrical current and a magnetic field to drive the magnetohydrodynamic motion of the cooling fluid 30. There are at least two options for harvesting and/or utilizing energy created by the plasma energy flow over the outer shell, these could be used independently or in tandem/unison. One option is to utilize the magnetic field generated on the exterior of the hypersonic glide vehicle due to the plasma 95 generated during flight.

Another option is to harvest the thermal energy generated on the exterior of the hypersonic glide vehicle during flight. The drive system 35 can harvest energy from the thermal energy by using thermoelectric generation.

It is possible to enhance the electrical conductivity of the surface of the hypersonic glide vehicle in order to better harvest the electrical field and/or magnetic field of the plasma 95 field surround the hypersonic vehicle. For example, in one embodiment, the hypersonic glide vehicle may have an outer housing 15 that is at least partially composed of materials that can be tuned for optimal thermal and electrical conductivity which allows for interrogation of the near surface electromagnetic fields.

### Example 2—Moderately High Temperature

Thermal management for high power electronics is increasingly more challenging as system power is increased in smaller electronic packaged systems. The increase in power results in an increase in temperature, with high powered electronics reaching temperatures ranging from 100-800 degrees Celsius. However, high power electronics are also often very compact, so it may not always be possible to increase the footprint of a cooling system within the electronic equipment. The inclusion of additional components, particularly large or expensive components, is undesirable. For example, adding more pumps, fans, or motors into a piece of electronic equipment is generally undesirable because it adds cost, complexity (and therefore may reduce reliability), and size to the overall electronic equipment.

Currently, high power computing commonly utilizes forced air convection via very high flowing fans, which has limited heat transfer capabilities. Localized heating problems still occur because fan flow curves are limited. Additionally, high flowing fans are undesirable in commercial applications due to the amount of noise with higher fan flow. Integrated heat pipes are also limited to passively cooling and conducting the heat out. Heat pipe assemblies tend to be expensive and are limited in cooling capacities. Many of the solutions being evaluated for high power electronics tend to be larger, heavier, include more components, and require motor driven components to induce flow. These additional complexities impact system reliability, SWaP, and cost.

The present disclosure provides a low cost integrated thermal management solution that takes advantage of additive manufacturing integrated with a simple, reliable, and low SWaP forced cooling solution utilizing magnetohydrodynamic pumping. Additionally, the liquid metal has high thermal conductivity, providing improved cooling capacity over other thermal coolants. The thermal management system 10 may be integrated into commercial electronic products, such as computers or other high-power systems, to improve the performance.

Although the disclosure has been described in detail with reference to certain preferred embodiments, variations and modifications exist within the scope and spirit of one or more independent aspects of the disclosure as described. Various features and advantages of the disclosure are set forth in the following claims.

What is claimed is:

1. A thermal management system, the system comprising:
a thermal structure forming a plurality of channels, the thermal structure being a thermally conductive material;
a cooling fluid configured to flow through the channels of the thermal structure, the cooling fluid being an electrically conducting fluid; and
a drive system configured to pump the cooling fluid through the channels of the thermal structure, wherein the drive system controls one or more electromagnetic field to induce magnetohydrodynamic pumping of the cooling fluid.

2. The cooling system of claim 1, wherein the cooling fluid is a metal or an electrically conductive fluid.

3. The cooling system of claim 1, wherein the cooling fluid is at least partially composed of at least one selected from the group consisting of Galinstan or Gallium (Ga).

4. The cooling system of claim 1, wherein the cooling fluid is stored in a solid phase and is selectively transition from solid to liquid state for increase thermal capacity or thermal magazine of the system.

5. The cooling system of claim 1, wherein the drive system includes one or more magnet(s) and one or more sets of electrodes configured to generate an electric field within the fluid, and wherein the drive system induces magnetohydrodynamic pumping of the cooling fluid by controlling the current into the cooling fluid via the electrodes.

6. The cooling system of claim 1, wherein the drive system includes a moving platform, and wherein the drive system harvests energy from the kinetic energy applied to the system by the moving platform.

7. The cooling system of claim 1, wherein the drive system induces the magnetohydrodynamic pumping of the cooling fluid by harvesting energy formed by the plasma energy flow over the shell of a hypersonic glide vehicle.

8. The cooling system of claim 1, wherein the drive system induces the magnetohydrodynamic pumping of the cooling fluid by harvesting thermal electrical energy.

9. The cooling system of claim 1, wherein the thermal structure is a porous material and an electrically insulative material.

10. The cooling system of claim 1, wherein the thermal structure is manufactured by an additive manufacturing process.

11. The cooling system of claim 10, wherein thermal structure is additively manufactured with at least one selected from the group consisting of a ceramic material and a silicon carbide.

12. The cooling system of claim 10, wherein the thermal structure is additively manufactured directly onto a surface of an item to be cooled.

13. The cooling system of claim 10, wherein the thermal structure is a Triply Periodic Minimal Surface (TPMS).

14. The cooling system of claim 1, further comprising an oscillating pipe, and wherein the cooling fluid is configured to flow through the pipe via fluid convection.

15. A thermal management system, the system comprising:
a thermal structure forming a plurality of channels, the thermal structure is an additively manufactured ceramic structure;
a cooling fluid configured to flow through the channels of the thermal structure, the cooling fluid being an electrically conducting metal or an electrically conducting fluid;
one or more sets of electrodes configured to apply a current to the system; and
a drive system configured to pump the cooling fluid through the channels of the thermal structure, the drive system operatively coupled to the one or more sets of electrodes to control the current applied to the system and induce magnetohydrodynamic pumping of the cooling fluid.

16. The cooling system of claim 15, wherein the cooling fluid is at least partially composed of at least one selected from the group consisting of Galinstan or Gallium (Ga).

17. The cooling system of claim 15, wherein the thermal structure is formed as at least one selected from the group consisting of a lattice structure, a Triply Periodic Minimal Surface (TPMS), an iso-grid, or a plurality of fins, or a combination thereof.

18. The cooling system of claim 15, wherein the thermal structure is additively manufactured with at least one selected from the group consisting of a ceramic material and a silicon carbide.

19. A thermal management system, the system comprising:
a thermal structure forming a plurality of channels, the thermal structure being a thermally conductive material, the thermal structured having a first end, a second end, a first side extending between the first end and second end, a second side opposite the first side and extending between the first end and the second end, a bottom extending between the first end and the second end, and a top opposite the bottom and extending between the first end and the second end;
a pair of electrodes positioned along the first side and the second side of the thermal structure, the pair of electrodes configured to induce a current between first side and the second side of the thermal structure;
one or more magnet positioned along the bottom of the thermal structure, the one or more magnet configured to induce a magnetic field perpendicular to the current;
a cooling fluid configured to flow through the channels of the thermal structure, the cooling fluid being an electrically conducting fluid; and
a control system configured to control magnetohydrodynamic pumping of the cooling fluid by controlling the current flowing between the pair of electrodes.

20. The cooling system of claim 19, further comprising an accumulator to store energy or harvest energy to drive magnetohydrodynamic flow of the cooling fluid.

21. The cooling system of claim 20, further comprising a moving platform, wherein the system is configured to harvest energy for the magnetohydrodynamic pumping of the cooling fluid from the kinetic energy applied to the system by the moving platform.

22. The cooling system of claim 19, wherein thermal structure is additively manufactured with a ceramic material, and wherein the thermal structure is formed as a Triply Periodic Minimal Surface (TPMS).
